(19) United States
(12) Patent Application Publication
(10) Pub. No.: US 2017/0069691 A1
(43) Pub. Date: Mar. 9, 2017

(54) DISPERSION LIQUID, TRANSPARENT CONDUCTIVE FILM, INPUT DEVICE, AND ORGANIC ELECTROLUMINESCENT LIGHTING DEVICE

(71) Applicant: Dexerials Corporation, Tokyo (JP)

(72) Inventors: Ryosuke IWATA, Tokyo (JP); Mikihisa MIZUNO, Utsunomiya-shi (JP)

(73) Assignee: Dexerials Corporation, Tokyo (JP)

(21) Appl. No.: 15/255,513

(22) Filed: Sep. 2, 2016

(30) Foreign Application Priority Data
Sep. 4, 2015 (JP) 2015-174867

(51) Int. Cl. H01L 27/32; G06F 3/044

(52) U.S. Cl. CPC H01L 27/323; G06F 3/044

(57) ABSTRACT

Provided is a dispersion liquid that enables formation of a transparent conductive film in which diffuse reflection of light by the surfaces of metal nanowires is prevented while maintaining good transparency, and in which yellow coloring is suppressed to provide the transparent conductive film with excellent external appearance. The dispersion liquid contains metal nanowires and a colored compound adsorbed onto the metal nanowires. A transmission b* value of a transparent conductive film formed from the dispersion liquid is no greater than 0.7.

### TECHNICAL FIELD

The present disclosure relates to a dispersion liquid, a transparent conductive film, an input device, and an organic electroluminescent lighting device.

### BACKGROUND

Transparent conductive films that are required to exhibit light transmittivity have been conventionally made from metal oxides such as indium tin oxide (ITO). Examples of such transparent conductive films include a transparent conductive film disposed on a display surface of a display panel and a transparent conductive film of an information input device disposed at a display surface-side of a display panel. However, a transparent conductive film made using a metal oxide has expensive production costs as a result of being formed by sputtering in a vacuum environment and is susceptible to cracking and delamination due to deformation by bending, warping, or the like.

Consequently, transparent conductive films made using metal nanowires are being developed as an alternative to transparent conductive films made using metal oxides. This is because a transparent conductive film made using metal nanowires can be formed by coating or printing and is highly resistant to bending and warping. Moreover, transparent conductive films made using metal nanowires are attracting attention as next generation transparent conductive films that are made without using the rare metal indium (for example, refer to PTL 1 and 2 shown below).

However, there has been a problem that in a situation in which a transparent conductive film made using metal nanowires is disposed at a display surface-side of a display panel, diffuse reflection of external light by the surfaces of the metal nanowires causes black displayed by the display panel to appear slightly brighter, which may be referred to as a “black floating (black level misadjustment)” phenomenon. The black floating phenomenon is a factor that leads to deterioration in display characteristics due to reduced contrast.

A technique using a gold nanotube made from gold (Au) has been proposed with the objective of preventing occurrence of the black floating phenomenon since gold has a lower tendency to diffusely reflect light. A gold nanotube is formed by initially using a silver nanowire having a high tendency to diffusely reflect light as a template and subjecting the silver nanowire to gold plating. Thereafter, the silver nanowire portion used as the template is etched or oxidized in order to carry out conversion to a gold nanotube (for example, refer to PTL 3 shown below).

Furthermore, a technique for preventing light scattering has been proposed (for example, refer to PTL 2 shown below) in which metal nanowires are used in combination with a secondary conductive medium (for example, CNTs (carbon nanotubes), a conductive polymer, or ITO).

However, in the case of the gold nanotube obtained by the method in PTL 3, not only is the silver nanowire used as a template wasted as a material, but a metal material is also required to perform the gold plating. Therefore, this method suffers from high production costs due to having high material costs and a complicated process.

Furthermore, in the case of the technique in PTL 2, there may be loss of transparency due to the secondary conductive medium (colorant material), such as CNTs, a conductive polymer, or ITO, being located in openings in a metal nanowire network.

In order to combat these problems, techniques are being developed in relation to transparent conductive films that include metal nanowires and a colored compound (dye) adsorbed onto the metal nanowires (for example, refer to PTL 4 and 5 shown below). Through use of a transparent conductive film including metal nanowires and a colored compound (dye) adsorbed onto the metal nanowires, it is possible to prevent diffuse reflection of light by the surfaces of the metal nanowires because the colored compound adsorbed onto the metal nanowires absorbs visible light and it is also possible to suppress reduction in transparency caused by addition of the colored compound (dye).

### CITATION LIST

### Patent Literature

PTL 1: JP-T-2010-507199

PTL 2: JP-T-2010-525526

PTL 3: JP-T-2010-525527

PTL 4: JP-A-2012-190777

PTL 5: JP-A-2012-190780

### SUMMARY

Although the techniques in PTL 4 and 5 achieve effects of preventing diffuse reflection of light by the surfaces of metal nanowires and preventing occurrence of black floating caused by this diffuse reflection, a transparent conductive film obtained by these techniques may have a yellow tinge and further improvement is desirable from a viewpoint of external appearance.

The present disclosure is made in light of the circumstances described above and an objective thereof is to provide a dispersion liquid that enables formation of a transparent conductive film in which diffuse reflection of light by the surfaces of metal nanowires is prevented while maintaining good transparency, and in which yellow coloring is suppressed to provide the transparent conductive film with excellent external appearance.

Another objective of the present disclosure is to provide, through use of the dispersion liquid according to the present disclosure, a transparent conductive film having excellent transparency and external appearance, and in which diffuse reflection of light by the surfaces of metal nanowires is prevented, and also to provide, through use of the transparent conductive film as an electrode, an input device and an organic electroluminescent lighting device having excellent external appearance and in which black floating does not occur.

The inventors conducted diligent research in relation to a dispersion liquid containing metal nanowires and a colored compound adsorbed onto the metal nanowires in order to solve the problems described above. As a result of this research, the inventors focused on a transmission b* value of a transparent conductive film formed from the dispersion liquid and discovered that by limiting the transmission b* value to no greater than a specific value, it is possible to suppress yellow coloring and improve external appearance compared to conventional metal nanowire-containing transparent conductive films.

The present disclosure is based on the findings described above and the primary features thereof are as follows.

(1) A dispersion liquid comprising: metal nanowires and a colored compound adsorbed onto the metal nanowires, wherein a transmission b* value of a transparent conductive film formed from the dispersion liquid is no greater than 0.7.

The configuration described above enables formation of a transparent conductive film in which diffuse reflection of light by the surfaces of metal nanowires is prevented while maintaining good transparency, and in which yellow coloring is suppressed to provide the transparent conductive film with excellent external appearance.

(2) The dispersion liquid described in (1), wherein a difference between the transmission b* value in a situation in which the transparent conductive film has a sheet resistance value of 40 Ω/sq. and the transmission b* value in a situation in which the transparent conductive film has a sheet resistance value of 100 Ω/sq. is no greater than 0.4.

(3) The dispersion liquid described in (1), wherein the colored compound is a phthalocyanine-based complex compound.

(4) The dispersion liquid described in (3), wherein the phthalocyanine-based complex compound is represented by general formula (1) shown below,

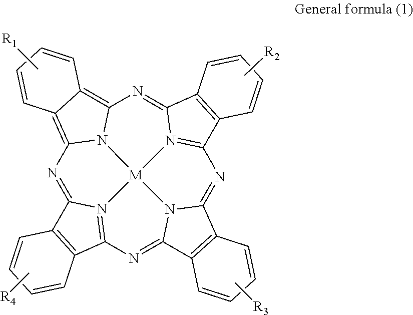

M in general formula (1) is any of Cu, Fe, Ti, V, Ni, Pd, Pt, Pb, Si, Bi, Cd, La, Tb, Ce, Be, Mg, Co, Ru, Mn, Cr, Mo, Sn, and Zn, and may be present or absent,

one or more of R₁ to R₄ in general formula (1) are present on a phthalocyanine moiety, each include an ion represented by any general formula in general formula group (A) shown below, and may be the same or different to one another,

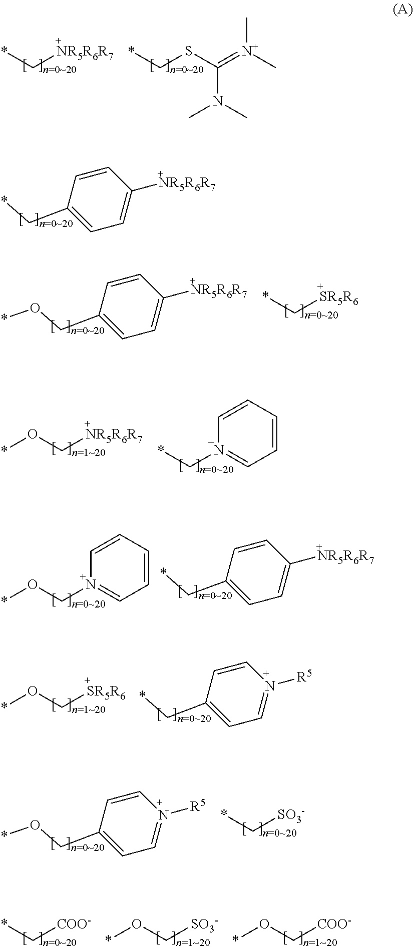

R₅ to R₇ in general formula group (A) are each hydrogen or a hydrocarbon group, and may be the same or different to one another,

R₁ to R₄ in general formula (1) each further include a counter ion represented by any general formula in general formula group (B) shown below,

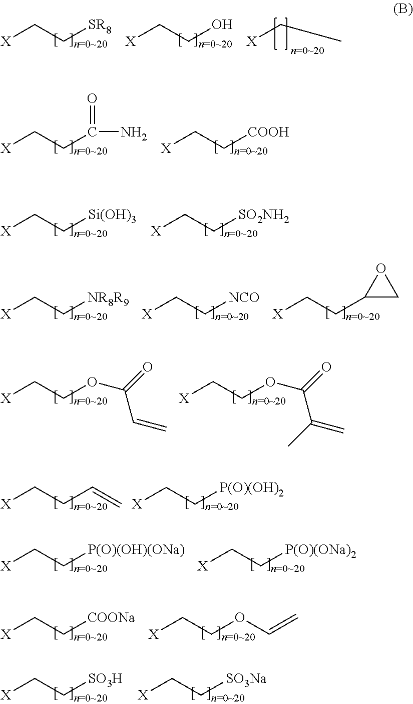

X in general formula group (B) is an ion represented by SO₃⁻, COO⁻, PO₃H⁻, PO₃²⁻, N⁺R₈R₉R₁₀, or PhN⁺R₈R₉R₁₀, an ion represented by general formula (2) shown below, or an ion represented by structural formula (1) shown below,

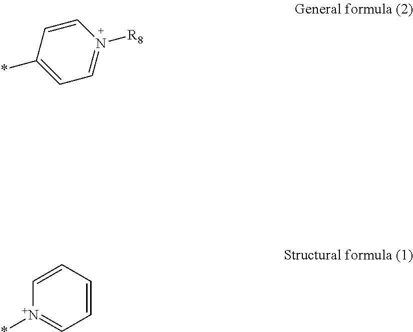

and R₈ to R₁₀ in general formula group (B), N⁺R₈R₉R₁₀, PhN⁺R₈R₉R₁₀, and general formula (2) are each hydrogen or a hydrocarbon group, and may be the same or different to one another.

(5) The dispersion liquid described in any one of (1) to (4), wherein a reflection L* value of the transparent conductive film is no greater than 10.

(6) A transparent conductive film comprising: metal nanowires and a colored compound adsorbed onto the metal nanowires, wherein a transmission b* value of the transparent conductive film is no greater than 0.7.

(7) An input device comprising the transparent conductive film described in (6).

(8) An organic electroluminescent lighting device comprising the input device described in (7).

According to the present disclosure, it is possible to provide a dispersion liquid that enables formation of a transparent conductive film in which diffuse reflection of light by the surfaces of metal nanowires is prevented while maintaining good transparency, and in which yellow coloring is suppressed to provide the transparent conductive film with excellent external appearance. Furthermore, it is possible to provide, using the dispersion liquid, a transparent conductive film in which good transparency is maintained and yellow coloring is suppressed to provide the transparent conductive film with excellent external appearance, and it is possible to provide, through use of the transparent conductive film as an electrode, an input device and an organic electroluminescent lighting device having excellent external appearance and in which black floating does not occur.

### BRIEF DESCRIPTION OF THE DRAWINGS

In the accompanying drawings:

FIG. 1 schematically illustrates one embodiment of a transparent electrode including a transparent conductive film according to the present disclosure;

FIG. 2 schematically illustrates another embodiment of a transparent electrode including a transparent conductive film according to the present disclosure;

FIG. 3 schematically illustrates another embodiment of a transparent electrode including a transparent conductive film according to the present disclosure;

FIG. 4 schematically illustrates another embodiment of a transparent electrode including a transparent conductive film according to the present disclosure;

FIG. 5 schematically illustrates another embodiment of a transparent electrode including a transparent conductive film according to the present disclosure;

FIG. 6 schematically illustrates another embodiment of a transparent electrode including a transparent conductive film according to the present disclosure; and

FIG. 7 illustrates one embodiment of main elements of configuration of an input device according to the present disclosure.

### DETAILED DESCRIPTION

The following provides a specific description of the present disclosure.

### <Dispersion Liquid>

First, a dispersion liquid according to the present disclosure is described.

The dispersion liquid according to the present disclosure is a dispersion liquid that contains metal nanowires and a colored compound adsorbed onto the metal nanowires.

A feature of the dispersion liquid according to the present disclosure is that a transmission b* value of a transparent conductive film formed from the dispersion liquid is no greater than 0.7.

As a result of components of the dispersion liquid being appropriately set such that the transmission b* value of the transparent conductive film formed therewith is no greater than 0.7, yellow coloring can be suppressed and superior external appearance can be achieved compared to conventional transparent conductive films.

(Metal Nanowires)

The metal nanowires contained in the dispersion liquid according to the present disclosure are metal nanowire bodies prior to adsorption of the colored compound.

Adsorption of the colored compound onto the metal nanowires can prevent diffuse reflection of light by the surfaces of the metal nanowires because the colored compound absorbs visible light. As a result, occurrence of black floating in the transparent conductive film can be suppressed.

Note that the metal nanowires may be inclusive not only of metal nanowires having the colored compound adsorbed onto the entirety thereof, but also metal nanowires having the colored compound adsorbed onto at least part thereof.

The metal nanowires are made from metal and are fine wires having nanometer-scale diameters.

A material of the metal nanowires can be selected as appropriate depending on the objective, without any specific limitations other than being a conductive metal material, and may for example be Ag, Au, Ni, Cu, Pd, Pt, Rh, Ir, Ru, Os, Fe, Co, Sn, Al, Tl, Zn, Nb, Ti, In, W, Mo, Cr, V, or Ta. Any one of these examples may be used alone or any two or more of these examples may be used in combination.

Among the constituent elements listed above, a metal material including the element Ag or Cu is preferable in terms of having high conductivity.

The average major axis length of the metal nanowires can be selected as appropriate depending on the objective, without any specific limitations, and is preferably from 1 μm to 100 μm, more preferably from 5 μm to 50 μm, and particularly preferably from 10 μm to 30 μm.

When the average major axis length of the metal nanowires is 1 μm or less, the metal nanowires have a poor tendency to join to one another and a transparent conductive film including metal nanowires obtained through adsorption treatment of such metal nanowires may not be able to function as a conductive film, whereas when the average major axis length of the metal nanowires is greater than 100 μm, a transparent conductive film including metal nanowires obtained through adsorption treatment of such metal nanowires with a colored compound may have poor total light transmittivity and haze, and the metal nanowires obtained through the adsorption treatment may have poor dispersibility in a dispersion liquid used in formation of the transparent conductive film. On the other hand, it is advantageous for the average major axis length of the metal nanowires to be in the more preferable range or the particularly preferable range described above because a transparent conductive film including metal nanowires obtained through adsorption treatment of such metal nanowires has high conductivity and high transparency.

Note that the average minor axis diameter and the average major axis length of the metal nanowires are respectively a number average minor axis diameter and a number average major axis length that can be measured using a scanning electron microscope. More specifically, at least 100 of the metal nanowires are measured and an image analyzer is used to calculate a projected diameter and a projected area of each nanowire from an electron microscope photograph. The projected diameter is taken to be the minor axis diameter. The major axis length is calculated based on the following formula.

Major axis length=Projected area/Projected diameter

The average minor axis diameter is the arithmetic mean of the minor axis diameters. The average major axis length is the arithmetic mean of the major axis lengths.

Furthermore, the metal nanowires may alternatively have a wire shape connecting metal nanoparticles in a bead-string shape. No specific limitations are placed on the length in such a situation.

The mass per unit area of the metal nanowires may be selected as appropriate depending on the target resistance value for the transparent conductive film and so forth, without any specific limitations, and is preferably from 0.001 g/m² to 1.000 g/m², and more preferably from 0.003 g/m² to 0.03 g/m².

When the mass per unit area of the metal nanowires is less than 0.001 g/m², the transparent conductive film may have poor conductivity because the metal nanowires are not sufficiently present in the transparent conductive film, whereas when the mass per unit area is greater than 1.000 g/m², the transparent conductive film may have poor total light transmittivity and haze. On the other hand, it is advantageous for the mass per unit area of the metal nanowires to be in the more preferable range or the particularly preferable range described above because the transparent conductive film has high conductivity and high transparency in such a situation.

(Colored Compound)

The colored compound contained in the dispersion liquid according to the present disclosure is in an adsorbed state on the metal nanowires and is an organic compound or a metal complex compound that absorbs visible region light. Herein, “visible region light” refers to light in a wavelength band from approximately 360 nm or greater to 830 nm or less. The colored compound described above includes a chromophore R that absorbs visible region light and a functional group X that bonds to a constituent metal of the metal nanowires and is represented by a general formula [R—X].

The chromophore [R] of the colored compound includes at least one of an unsaturated alkyl group, an aromatic ring, a heterocyclic ring, and a metal ion. Specific examples of the chromophore [R] include a nitroso group, a nitro group, an azo group, a methine group, an amino group, a ketone group, a thiazolyl group, a naphthoquinone group, a stilbene derivative, an indophenol derivative, a diphenylmethane derivative, an anthraquinone derivative, a triarylmethane derivative, a diazine derivative, an indigoid derivative, a xanthene derivative, an oxazine derivative, a porphyrin derivative, a phthalocyanine derivative, an acridine derivative, a thiazine derivative, a sulfur atom-containing compound, carbon nanotubes, carbon black, graphene, a fullerene, graphite, and a metal ion-containing compound. The chromophore [R] can be one or more selected from the group consisting of the examples of chromophores listed above and compounds including these chromophores.

The functional group [X] is a moiety including an adsorption group that is adsorbed onto a constituent metal of the metal nanowires. The functional group [X] can be selected as appropriate depending on the objective, without any specific limitations other than including the adsorption group, and examples thereof include a sulfo group (inclusive of sulfonic acid salts), a sulfonyl group, a sulfonamide group, a carboxylic acid group (inclusive of carboxylic acid salts), an aromatic amino group, an amide group, a phosphate group (inclusive of phosphoric acid salts and phosphoric acid esters), a phosphino group, a silanol group, an epoxy group, an isocyanate group, a cyano group, a vinyl group, a thiol group, a sulfide group, a carbinol group, an ammonium group, a pyridinium group, a hydroxy group, or an atom (for example, N (nitrogen), S (sulfur), or O (oxygen)) that can coordinate to the constituent metal of the metal nanowires. Any one of these examples may be used alone or any two or more of these examples may be used in combination. Such functional groups are selected as appropriate in consideration of solubility. On the other hand, an alkyl substituted amino group is preferably not used as this group may corrode metal filler. Herein, “alkyl substituted amino group” refers to an amino group in which all carbon atoms bonded directly to the N atom have sp³ hybridized orbitals. Furthermore, the aforementioned adsorption group is bonded to the chromophore R as the functional group [X] by covalent bonding or non-covalent bonding.

Moreover, a self-organizing material may be used as the colored compound including the functional group [X]. Furthermore, the functional group [X] may constitute part of the chromophore [R]. Note that regardless of whether or not a colored compound includes a functional group [X], a functional group [X] can be added through a chemical reaction between a compound including a chromophore [R] and a compound including a functional group [X].

The method by which the colored compound is produced can be selected as appropriate depending on the objective, without any specific limitations. For example, a method may be adopted that involves preparing a solution in which a raw material including the chromophore [R] is dissolved or dispersed in a solvent and a solution in which a compound including the functional group [X] that bonds to the metal nanowires is dissolved in a solvent, and mixing the two prepared solutions to cause precipitation of the colored compound.

Examples of the solvent mentioned above include water; alcohols such as methanol, ethanol, n-propanol, i-propanol, n-butanol, i-butanol, sec-butanol, and tert-butanol; ketones such as cyclohexanone and cyclopentanone; amides such as N,N-dimethylformamide (DMF); and sulfides such as dimethyl sulfoxide (DMSO). The solvent is selected as most appropriate in consideration of solubility of the raw materials and the product, and may be a single type of solvent or a combination of two or more types of solvents. Furthermore, the solvent may be added partway through. The temperature of the solutions is determined in consideration of solubility of the raw materials and the product and the rate of reaction, without any specific limitations.

Specific examples of the colored compound include acidic dyes and direct dyes. More specific examples of dyes that can be used include sulfo group-containing dyes such as Kayakalan Bordeaux BL, Kayakalan Brown GL, Kayakalan Gray BL167, Kayakalan Yellow GL143, Kayakalan Black 2RL, Kayakalan Black BGL, Kayakalan Orange RL, Kayarus Cupro Green G, Kayarus Supra Blue MRG, and Kayarus Supra Scarlet BNL200 produced by Nippon Kayaku Co., Ltd., and Lanyl Olive BG produced by Taoka Chemical Co., Ltd. Other examples include Kayalon Polyester Blue 2R-SF, Kayalon Microester Red AQ-LE, Kayalon Polyester Black ECX300, and Kayalon Microester Blue AQ-LE produced by Nippon Kayaku Co., Ltd. Examples of carboxyl group-containing dyes that can be used include pigments for dye-sensitized solar cells such as Ru complexes exemplified by N3, N621, N712, N719, N749, N773, N790, N820, N823, N845, N886, N945, K9, K19, K23, K27, K29, K51, K60, K66, K69, K73, K77, Z235, Z316, Z907, Z907Na, Z910, Z991, CYC-B1, and HRS-1, and organic pigments exemplified by Anthocyanine, WMC234, WMC236, WMC239, WMC273, PPDCA, PTCA, BBAPDC, NKX-2311, NKX-2510, NKX-2553 (produced by Hayashibara Co., Ltd.), NKX-2554 (produced by Hayashibara Co., Ltd.), NKX-2569, NKX-2586, NKX-2587 (produced by Hayashibara Co., Ltd.), NKX-2677 (produced by Hayashibara Co., Ltd.), NKX-2697, NKX-2753, NKX-2883, NK-5958 (produced by Hayashibara Co., Ltd.), NK-2684 (produced by Hayashibara Co., Ltd.), Eosin Y, Mercurochrome, MK-2 (produced by Soken Chemical & Engineering Co., Ltd.), D77, D102 (produced by Mitsubishi Paper Mills, Ltd.), D120, D131 (produced by Mitsubishi Paper Mills, Ltd.), D149 (produced by Mitsubishi Paper Mills, Ltd.), D150, D190, D205 (produced by Mitsubishi Paper Mills, Ltd.), D358 (produced by Mitsubishi Paper Mills, Ltd.), JK-1, JK-2, 5, ZnTPP, H2TC1PP, H2TC4PP, Phthalocyanine Dye (zinc phthalocyanine-2,9,16,23-tetra-carboxylic acid), 2-[2′-(zinc 9′,16′,23′-tri-tert-butyl-29H,31H-phthalocyanyl)] succinic acid, Polythiophene Dye (TT-1), Pendant type polymer, and Cyanine Dye (P3TTA, C1-D, SQ-3, B1).

From a viewpoint of achieving even better adsorption properties with respect to the metal nanowires and an even better inhibitive effect with respect to scattering of external light, it is preferable that the colored compound is a phthalocyanine-based complex compound.

The phthalocyanine-based complex compound is preferably represented by general formula (1) shown below.

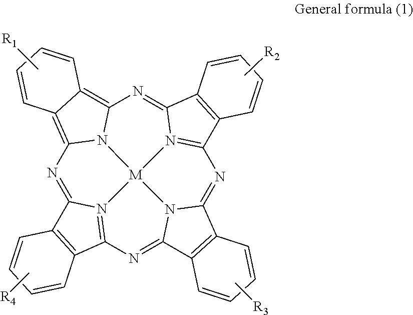

M in general formula (1) is any of Cu, Fe, Ti, V, Ni, Pd, Pt, Pb, Si, Bi, Cd, La, Tb, Ce, Be, Mg, Co, Ru, Mn, Cr, Mo, Sn, and Zn, and may be present or absent.

One or more of R₁ to R₄ in general formula (1) are present on a phthalocyanine moiety, each include an ion represented by any general formula in general formula group (A) shown below, and may be the same or different to one another.

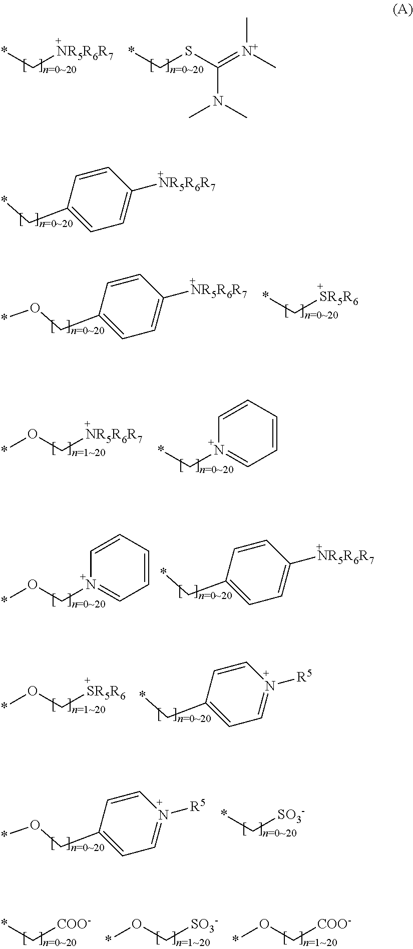

R₅ to R₇ in general formula group (A) are each hydrogen or a hydrocarbon group, and may be the same or different to one another.

R₁ to R₄ in general formula (1) each further include a counter ion represented by any general formula in general formula group (B) shown below.

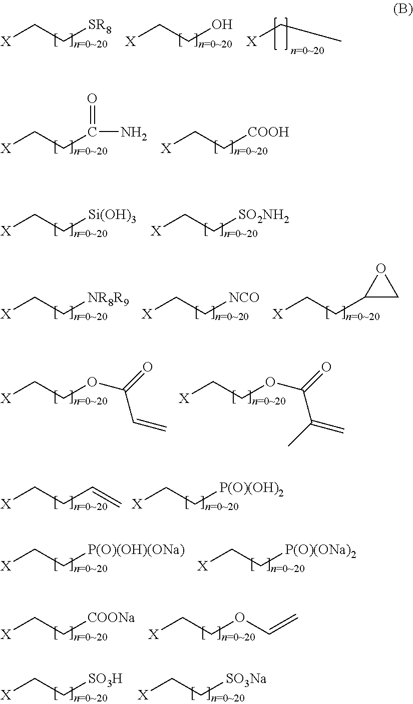

X in general formula group (B) is an ion represented by SO₃⁻, COO⁻, PO₃H⁻, PO₃²⁻, N⁺R₈R₉R₁₀, or PhN⁺R₈R₉R₁₀, an ion represented by general formula (2) shown below, or an ion represented by structural formula (1) shown below.

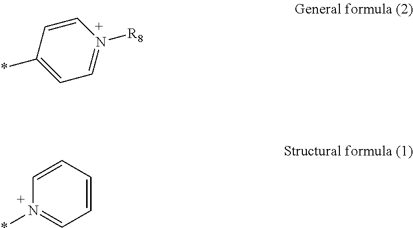

R₈ to R₁₀ in general formula group (B), N⁺R₈R₉R₁₀, PhN⁺R₈R₉R₁₀, and general formula (2) are each hydrogen or a hydrocarbon group, and may be the same or different to one another.

Even better adsorption properties with respect to the metal nanowires and an even better inhibitive effect with respect to scattering of external light can be realized as a result of the phthalocyanine moiety in the phthalocyanine-based complex compound represented by general formula (1) (i.e., a part of general formula (1) excluding R₁ to R₄) acting as the chromophore R of the colored compound and as a result of R₁ to R₄ in the phthalocyanine-based complex compound each acting as the functional group [X].

The E1% 1 cm value of the phthalocyanine-based complex compound at a wavelength of maximum absorption in the visible light region can be selected as appropriate depending on the objective, without any specific limitations, and is preferably at least 300, and more preferably at least 400.

When the E1% 1 cm value is at least 300, scattering of external light can be efficiently inhibited, and when the E1% 1 cm value is in the more preferable range, the inhibitive effect on scattering of external light is remarkable.

The solubility of the phthalocyanine-based complex compound with respect to water or ethylene glycol can be selected as appropriate depending on the objective, without any specific limitations, and is preferably at least 0.01 mass % and more preferably 0.02 mass % relative to the mass of the water or ethylene glycol.

When the solubility is at least 0.01 mass %, the amount of solvent used in surface treatment can be reduced, and when the solubility is in the more preferable range, the amount of solvent can be further reduced, thereby enabling surface treatment to be performed smoothly.

The number average particle diameter of the phthalocyanine-based complex compound when dispersed or dissolved as molecules in water or ethylene glycol can be selected as appropriate depending on the objective, without any specific limitations, and is preferably no greater than 3 μm, and more preferably no greater than 1 μm.

An average particle diameter of no greater than 3 μm can negate the negative influence of the phthalocyanine-based complex compound on total light transmittivity and an average particle diameter in the more preferable range can effectively inhibit scattering of external light.

The concentration of hydrogen ions (pH) when 0.1 mass % of the phthalocyanine-based complex compound is dissolved in water can be selected as appropriate depending on the objective, without any specific limitations, and is preferably 4-10, and more preferably 5-9.

When the concentration of hydrogen ions (pH) is 4-10, the nanowires have a low tendency to be corroded, and when the concentration of hydrogen ions (pH) is in the more preferable range, the nanowires have a very low tendency to be corroded and have good durability.

The phthalocyanine-based complex compound can be selected as appropriate depending on the objective, without any specific limitations, and may for example be a phthalocyanine-based complex compound represented by any of structural formulae (2) to (9) shown below. Furthermore, two or more of such phthalocyanine-based complex compounds may be mixed together.

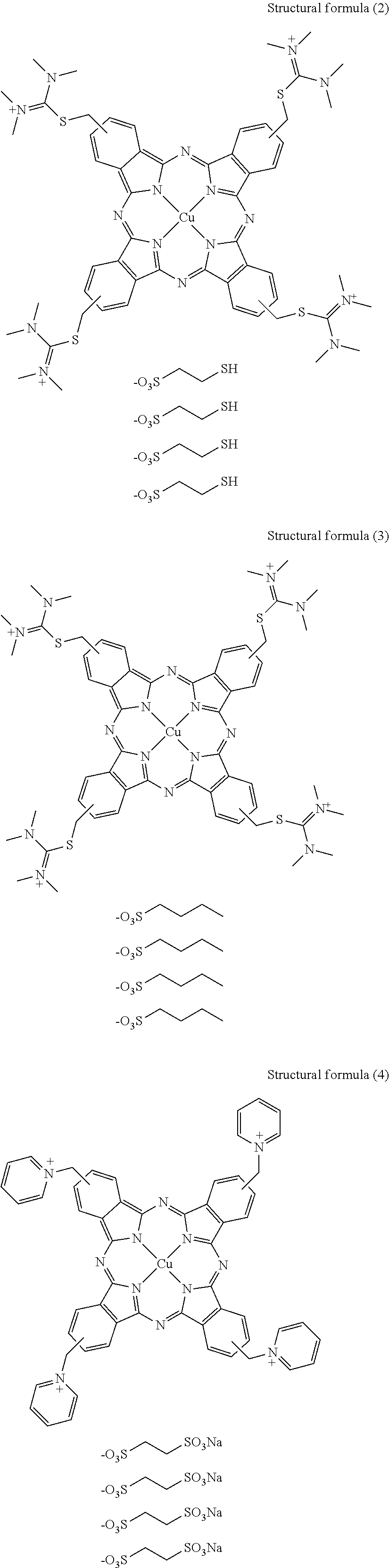

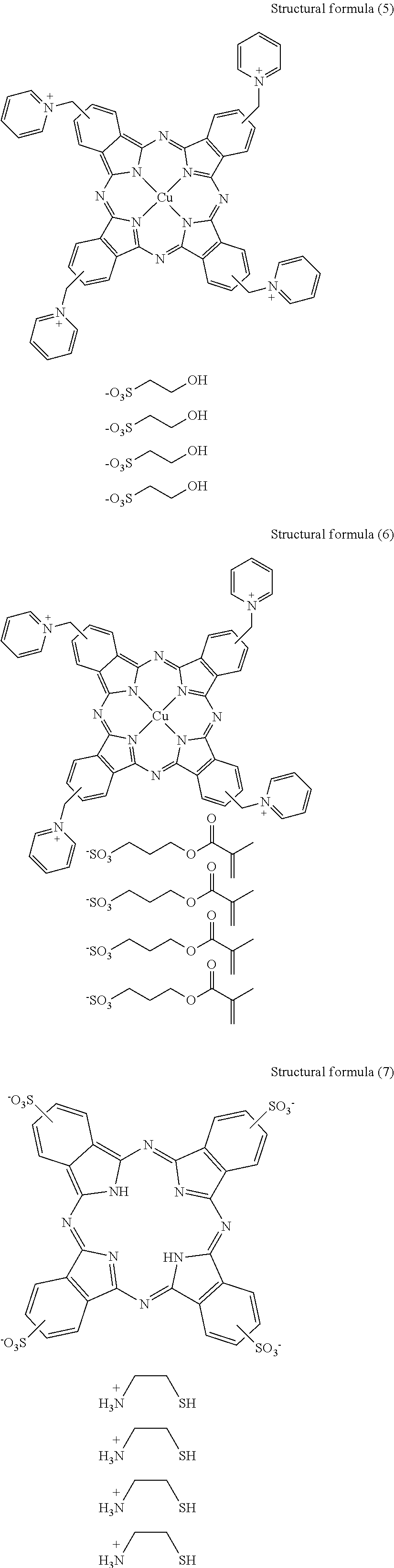

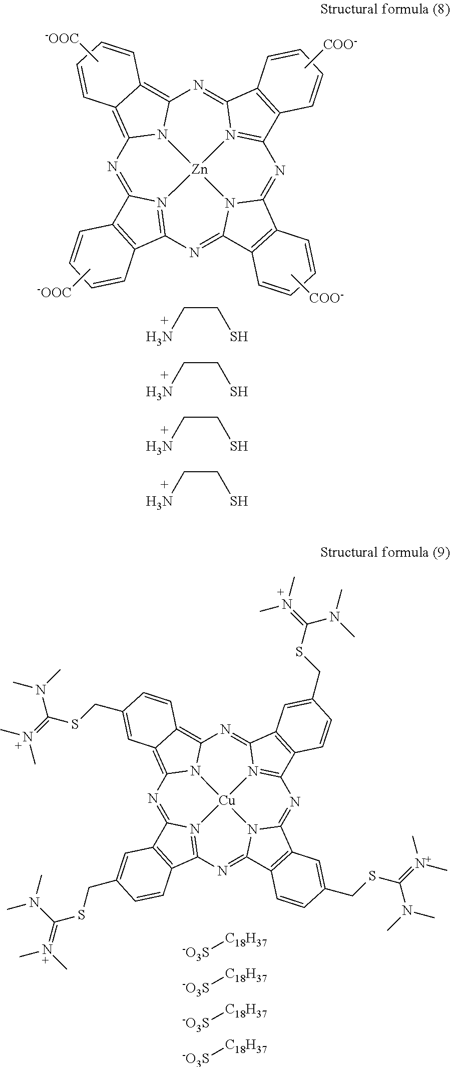

The phthalocyanine-based complex compound can be obtained by preparing a raw material solution in which a raw material including a phthalocyanine derivative moiety is dissolved in a solvent and a compound solution in which a compound including a moiety that bonds to the metal nanowires (i.e., the functional group [X]) is dissolved in a solvent, and mixing the raw material solution and the compound solution to precipitate the phthalocyanine-based complex compound. It should be noted that “dissolved” used herein is inclusive of not only a dissolved state but also a dispersed state.

The raw material including the phthalocyanine derivative moiety can be selected as appropriate depending on the objective, without any specific limitations. Examples of the raw material include alcian blue, alcian blue-tetrakis(methypyridinium) chloride, phthalocyanine tetrasulfonic acid, phthalocyanine monosulfonic acid, phthalocyanine disulfonic acid, phthalocyanine trisulfonic acid, phthalocyanine tetracarboxylic acid, phthalocyanine monocarboxylic acid, phthalocyanine dicarboxylic acid, phthalocyanine tricarboxylic acid, copper phthalocyanine tetra sulfonic acid tetrasodium salt, copper phthalocyanine monosulfonic acid tetrasodium salt, copper phthalocyanine disulfonic acid tetrasodium salt, copper phthalocyanine trisulfonic acid tetrasodium salt, copper phthalocyanine tetracarboxylic acid tetrasodium salt, copper phthalocyanine monocarboxylic acid tetrasodium salt, copper phthalocyanine dicarboxylic acid tetrasodium salt, and copper phthalocyanine tricarboxylic acid tetrasodium salt.

The compound including the moiety X that is adsorbed onto the metal can be selected as appropriate depending on the objective, without any specific limitations. Examples of the aforementioned compound include sodium 2-mercapto-1-ethanesulfonate, sodium butanesulfonate, disodium 1,2-ethanedisulfonate, sodium isethionate, potassium 3-(methacryloyloxy)propanesulfonate, 2-aminoethanethiol, sodium 1-octadecanesulfonate, sodium 3-mercapto-1-propanesulfonate, 2-aminoethanol hydrochloride, sodium 2,3-dimercaptopropanesulfonate, sodium 4-[(5-mercapto-1,3,4-thiadiazol-2-yl)thio]-1-butanesulfonate, sodium mercaptoacetate, sodium 2-(5-mercapto-1H-tetrazol-1-yl)acetate, 5-carboxy-1-pentanethiol sodium salt, 7-carboxy-1-heptanethiol sodium salt, 10-carboxy-1-decanethiol sodium salt, 15-carboxy-1-pentadecanethiol sodium salt, carboxy-EG6-undecanethiol sodium salt, and carboxy-EG6-hexadecanethiol sodium salt.

The solvent used for dissolution can be selected as appropriate depending on the objective, without any specific limitations. The solvent may for example be water; an alcohol such as methanol, ethanol, n-propanol, i-propanol, n-butanol, i-butanol, sec-butanol, or tert-butanol; a ketone such as cyclohexanone or cyclopentanone; an amide such as N,N-dimethylformamide (DMF); or a sulfide such as dimethyl sulfoxide (DMSO). The solvent is selected as most appropriate in consideration of solubility of the raw materials and the product, and may be a single type of solvent or a combination of two or more types of solvents. Furthermore, the solvent may be added partway through. The temperature of the solutions is determined in consideration of the solubility of the raw materials and the product and the rate of reaction, without any specific limitations.

Colored compound that is not adsorbed onto the metal nanowires is preferably removed to as great an extent as possible. The reason for this is that unattached colored compound in the dispersion liquid, which is superfluous, is a cause of reduced transparency of the transparent conductive film that is formed. Specifically, the concentration of unattached colored compound in the dispersion liquid is preferably no greater than 0.5 ppm, more preferably no greater than 0.3 ppm, and particularly preferably no greater than 0.15 ppm.

(Solvent)

The dispersion liquid according to the present disclosure may further contain a solvent in addition to the metal nanowires and the colored compound described above.

No specific limitations are placed on the solvent other than being a solvent in which the metal nanowires having the colored compound adsorbed thereon can be dispersed. Specifically, the solvent may for example be water; an alcohol such as methanol, ethanol, n-propanol, i-propanol, n-butanol, i-butanol, sec-butanol, or tert-butanol; a anone such as cyclohexanone or cyclopentanone; an amide such as N,N-dimethylformamide (DMF); or a sulfide such as dimethyl sulfoxide (DMSO). Any one of these solvents may be used alone or any two or more of these solvents may be used in combination.

In order to inhibit uneven drying, cracking, and whitening of the formed transparent conductive film, a high-boiling point solvent may be added to the dispersion liquid in order to control the rate of solvent evaporation from the dispersion liquid. The high-boiling point solvent may for example be butyl cellosolve, diacetone alcohol, butyl triglycol, propylene glycol monomethyl ether, propylene glycol monoethyl ether, ethylene glycol monoethyl ether, ethylene glycol monopropyl ether, ethylene glycol monoisopropyl ether, diethylene glycol monobutyl ether, diethylene glycol monoethyl ether, diethylene glycol monomethyl ether, diethylene glycol diethyl ether, dipropylene glycol monomethyl ether, tripropylene glycol monomethyl ether, propylene glycol monobutyl ether, propylene glycol isopropyl ether, dipropylene glycol isopropyl ether, tripropylene glycol isopropyl ether, or methyl glycol. Any of these high-boiling point solvents may be used alone or a plurality of these high-boiling point solvents may be used in combination.

(Resin Material)

The dispersion liquid according to the present disclosure may further contain a resin material in addition to the metal nanowires, the colored compound, and the solvent described above.

The resin material is used in order to disperse the metal nanowires having the colored compound adsorbed thereon and is what is referred to as a “binder material”. The resin material used herein can be selected from a wide range of known transparent natural polymer resins and synthetic polymer resins, and may for example be a thermoplastic resin, a thermosetting resin, or a photocurable resin.

The thermoplastic resin may be selected as appropriate depending on the objective, without any specific limitations, and may for example be polyvinyl chloride, a vinyl chloride-vinyl acetate copolymer, polymethyl methacrylate, nitrocellulose, chlorinated polyethylene, chlorinated polypropylene, vinylidene fluoride, ethylcellulose, hydroxypropyl methylcellulose, polyvinyl alcohol, or polyvinyl pyrrolidone.

The thermosetting resin may be selected as appropriate depending on the objective, without any specific limitations, and may for example be a composition including (i) a polymer such as polyvinyl alcohol, a polyvinyl acetate-based polymer (for example, saponified polyvinyl acetate), a polyoxyalkylene-based polymer (for example, polyethylene glycol or polypropylene glycol), or a cellulosic polymer (for example, methylcellulose, viscose, hydroxyethyl cellulose, hydroxyethyl methylcellulose, carboxymethyl cellulose, or hydroxypropyl methylcellulose), and (ii) a cross-linking agent such as a metal alkoxide, a diisocyanate compound, or a blocked isocyanate compound.

A positive-type photosensitive resin may be selected as appropriate depending on the objective, without any specific limitations, and may for example be a commonly known positive-type photoresist material such as a composition including (i) a polymer such as a novolac resin, an acrylic copolymer resin, or a hydroxypolyamide and (ii) a naphthoquinonediazide compound.

A negative-type photosensitive resin may be selected as appropriate depending on the objective, without any specific limitations, and may for example be (i) a polymer having a photosensitive group introduced onto either or both of a main chain and a side chain thereof, (ii) a composition including a binder resin (polymer) and a cross-linking agent, or (iii) a composition including a photopolymerization initiator and either or both of a (meth)acrylic monomer and a (meth)acrylic oligomer. The chemical reaction of the negative-type photosensitive material can be selected as appropriate depending on the objective, without any specific limitations, and may for example be (a) photopolymerization through a photopolymerization initiator, (b) photodimerization of stilbene, maleimide, or the like, or (c) crosslinking through photolysis of an azide group, a diazirine group, or the like. Among these examples, (c) cross-linking through photolysis of an azide group, a diazirine group, or the like is preferable in terms of curing reactivity as the reaction is not inhibited by oxygen and the resultant cured film (transparent conductive film) has excellent solvent resistance, hardness, and scratch resistance.

(Other Components)

The dispersion liquid according to the present disclosure may contain various additives as required in addition to the metal nanowires, the colored compound, the solvent, and the resin material described above.

Examples of additives that can be used include a light stabilizer, an ultraviolet absorber, a light absorber, an antistatic agent, a lubricant, a leveling agent, a defoamer, a flame retardant, an infrared absorber, a surfactant, a viscosity modifier, a dispersant, a curing accelerator catalyst, a plasticizer, an antioxidant, and a sulfurization inhibitor.

Examples of dispersants that can be used include polyvinyl pyrrolidone (PVP) and compounds that can be adsorbed onto metal and that have a functional group such as a sulfo group (inclusive of sulfonic acid salts), a sulfonyl group, a sulfonamide group, a carboxylic acid group (inclusive of carboxylic acid salts), an amide group, a phosphate group (inclusive of phosphoric acid salts and phosphoric acid esters), a phosphino group, a silanol group, an epoxy group, an isocyanate group, a cyano group, a vinyl group, a thiol group, or a carbinol group.

(Dispersion Liquid Production)

No specific limitations are placed on the method by which the dispersion liquid according to the present disclosure is produced so long as the produced dispersion liquid contains metal nanowires and a colored compound adsorbed onto the metal nanowires and a transmission b* value of a transparent conductive film formed from the dispersion liquid is no greater than 0.7.

The dispersion liquid can for example be produced by performing, in stated order, (1) a step of preparing a colored compound solution, (2) a step of causing adsorption of the colored compound onto metal nanowires and (3) a step of removing colored compound that has not been adsorbed.

Once (3) the step of removing colored compound that has not been adsorbed has been carried out, the dispersion liquid according to the present disclosure can be produced by adding the solvent and the resin material described above to the resultant metal nanowires having the colored compound adsorbed thereon, and further adding the additives described above as appropriate.

Herein, (1) the step of preparing the colored compound solution is a step in which the colored compound described above is dissolved in a solvent in order to obtain the colored compound solution. Furthermore, (2) the step of causing adsorption of the colored compound onto metal nanowires is a step in which the colored compound solution is mixed with a metal filler dispersion liquid containing the metal nanowires described above and a solvent, and the resultant mixture is subsequently left to stand, stirred, heated, or the like for a specific period of time in order to cause adsorption of the colored compound onto the metal nanowires. Moreover, (3) the step of removing colored compound that has not been adsorbed is a step in which the mixed solution described above is filtered in order to remove colored compound present in the mixed solution. Although no specific limitations are placed on the filtration method, it is preferable that the mixed solution containing the metal nanowires having the colored compound adsorbed thereon is added into a filter paper tube and that colored compound that has not been adsorbed is removed by filtration in accompaniment to the solvent, and it is also preferable that the filtration is carried out while constantly adding solvent into the filter paper tube because this allows more reliable removal of superfluous colored compound.

<Transparent Conductive Film>

The following describes a transparent conductive film formed using the dispersion liquid according to the present disclosure with reference to the drawings as necessary.

The transparent conductive film formed using the dispersion liquid according to the present disclosure (i.e., a transparent conductive film according to the present disclosure) includes metal nanowires and a colored compound adsorbed onto the metal nanowires and has a transmission b* value of no greater than 0.7.

As a result of the transparent conductive film having a transmission b* value of no greater than 0.7, it is possible to suppress yellow coloring and obtain excellent external appearance compared to conventional transparent conductive films.

From a viewpoint of obtaining even better external appearance, the transmission b* value of the transparent conductive film is preferably no greater than 0.6. Although no specific restrictions are placed on the lower limit for the transmission b* value, the transmission b* value is preferably at least −1 in order to suppress other coloring (for example, blue coloring).

The transmission b* value is the value of b* for light transmitted by the transparent conductive film. Likewise, reflection L* and transmission a* values are values of L* for reflected light and a* for transmitted light.

Furthermore, it is preferable that the difference between the transmission b* value in a situation in which the transparent conductive film has a sheet resistance value of 40 Ω/sq. and the transmission b* value in a situation in which the transparent conductive film has a sheet resistance value of 100 Ω/sq. is no greater than 0.4 (i.e., [transmission b* value for sheet resistance value of 40 Ω/sq.]−[transmission b* value for sheet resistance value of 100 Ω/sq.]≦0.4). The reason for this is that it allows the transparent conductive film according to the present disclosure to be used for a wider range of sheet resistance values.

In order to provide the transparent conductive film with a lower sheet resistance value, it is necessary to increase the mass per unit area of the metal nanowires (i.e., increase the metal nanowire content in the transparent conductive film) in order to increase the conductivity. As a result of there only being a small difference between the transmission b* value in a situation in which the transparent conductive film has a low sheet resistance value (40 Ω/sq.) and the transmission b* value in a situation in which the transparent conductive film has a high sheet resistance value (100 Ω/sq.), the transmission b* value is lower than 0.7 for a wide range of sheet resistance values. Consequently, the transparent conductive film according to the present disclosure can be used for a wide range of sheet resistance values.

Although no specific limitations are placed on the Δreflection L* value of the transparent conductive film, the Δreflection L* value is preferably no greater than 10, and more preferably no greater than 5. The reason for this is that when the Δreflection L* value is high, black floating is more likely to occur in a situation in which the transparent conductive film is installed in front of a display device.

Furthermore, although no specific limitations are placed on the transmission a* value of the transparent conductive film, the transmission a* value is preferably from −2 to 2, and more preferably from −1 to 1. The reason for this is that reducing the absolute value of the transmission a* value to as small a value as possible makes the transparent conductive film closer to being colorless and transparent.

(Transparent Electrode Formation)

A transparent electrode can be formed using the transparent conductive film according to the present disclosure. The configuration of the transparent electrode can be selected as appropriate depending on the objective, without any specific limitations.

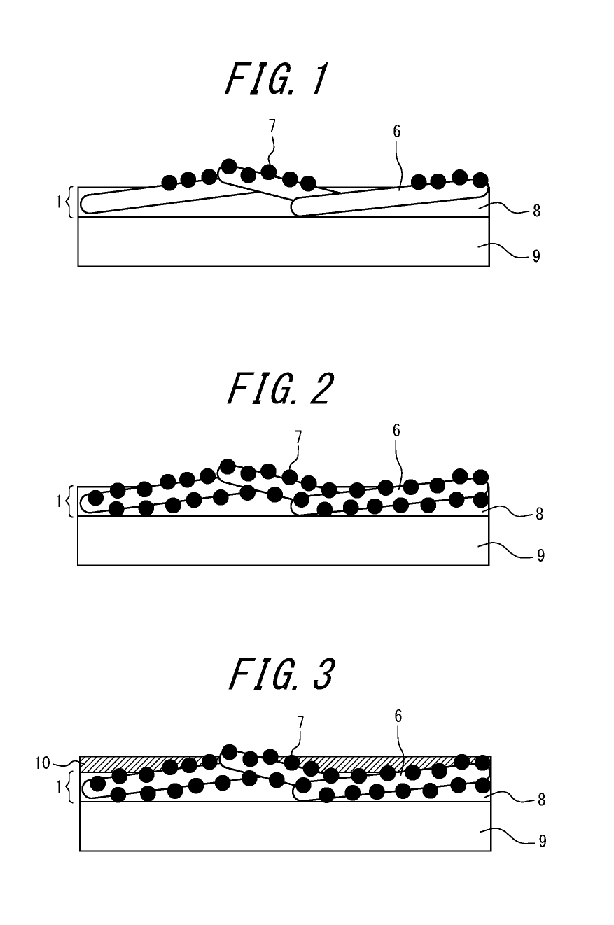

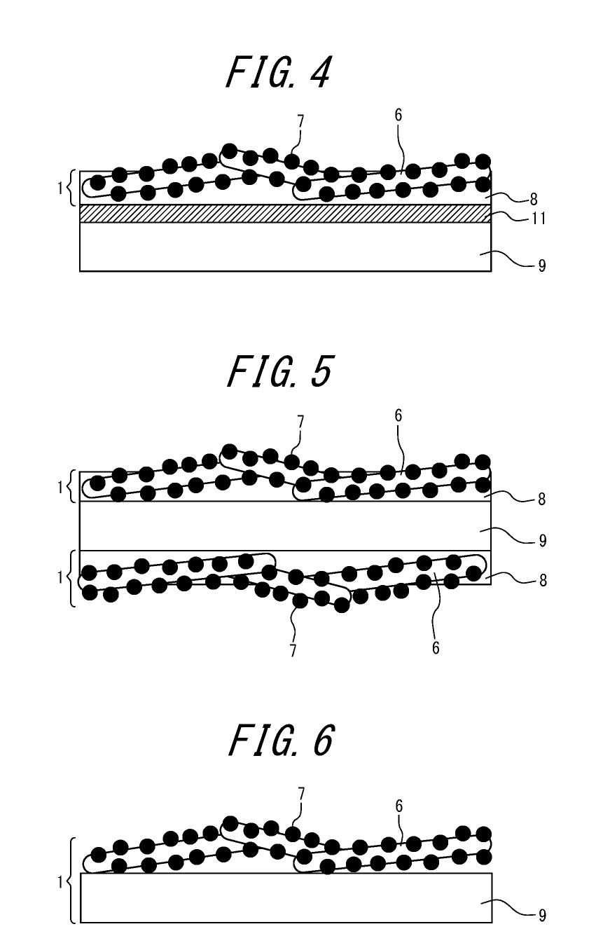

Examples of configurations that can be adopted include (i) a transparent conductive film 1 such as illustrated in FIG. 1 in which a colored compound (dye) 7 is only adsorbed onto sections of metal nanowires 6 that are exposed from a binder layer (the colored compound (dye) 7 may be adsorbed onto the metal nanowires 6, and may be present on part of the surface of the binder layer 8 or within the binder layer 8), (ii) a transparent conductive film 1 such as illustrated in FIG. 2 in which a binder layer 8 is formed on a substrate 9 and in which metal nanowires 6 having a colored compound 7 adsorbed thereon are dispersed in the binder layer 8, (iii) a transparent conductive film 1 such as illustrated in FIG. 3 in which an overcoating layer 10 is formed above a binder layer 8, (iv) a transparent conductive film 1 such as illustrated in FIG. 4 in which an anchor layer 11 is formed between a binder layer 8 and a substrate 9, (v) a transparent conductive film 1 such as illustrated in FIG. 5 in which a binder layer 8 including metal nanowires 6 having a colored compound 7 adsorbed thereon is formed on both surfaces of a substrate 9, (vi) a transparent conductive film 1 such as illustrated in FIG. 6 in which metal nanowires 6 having a colored compound 7 adsorbed thereon are accumulated on top of a substrate 9 without the colored compound 7 being dispersed in a binder, or (vii) a combination of any of (i) to (vi).

The substrate can be selected as appropriate depending on the objective, without any specific limitations, and is preferably a transparent substrate made from a material that transmits visible light such as an inorganic material or a plastic material. The transparent substrate is of a thickness required for a transparent electrode including a transparent conductive film, and is for example a film shape (sheet shape) that is thin enough to exhibit flexible bending or a base plate shape that is thick enough to enable an appropriate degree of both bending and rigidity.

The inorganic material can be selected as appropriate depending on the objective, without any specific limitations, and may for example be quartz, sapphire, or glass.

The plastic material can be selected as appropriate depending on the objective, without any specific limitations, and may for example be a commonly known polymer material such as triacetyl cellulose (TAC), polyester (TPEE), polyethylene terephthalate (PET), polyethylene naphthalate (PEN), polyimide (PI), polyamide (PA), an aramid, polyethylene (PE), polyacrylate, polyether sulfone, polysulfone, polypropylene (PP), diacetyl cellulose, polyvinyl chloride, an acrylic resin (PMMA), polycarbonate (PC), an epoxy resin, a urea resin, a urethane resin, a melamine resin, or a cycloolefin polymer (COP). In a situation in which the transparent substrate is made from the plastic material, the transparent substrate preferably has a thickness of from 5 μm to 500 μm from a viewpoint of producibility, but is not specifically limited to this range.

It is important that the overcoating layer described above displays light transmittivity with respect to visible light. The overcoating layer may for example be made from a polyacrylic-based resin, a polyamide-based resin, a polyester-based resin, or a cellulosic resin, or may be made from a metal alkoxide hydrolysis or dehydration condensation product. The overcoating layer described above is of a thickness that does not impair light transmittivity with respect to visible light. The overcoating layer has one or more functions selected from the group of functions consisting of hard coating, glare prevention, reflection prevention, Newton ring prevention, and blocking prevention.

The anchor layer described above can be selected as appropriate depending on the objective, without any specific limitations other than being a layer that enables stronger adhesion between the substrate and the binder layer.

(Transparent Conductive Film Production)

No specific limitations are placed on the method by which the transparent conductive film according to the present disclosure is produced so long as the transmission b* value of the produced transparent conductive film is no greater than 0.7. The method can for example include a dispersion film formation step, a curing step, a calendering step, an overcoating layer formation step, a pattern electrode formation step, and so forth.

The dispersion film formation step is a step in which the metal nanowire-containing dispersion liquid described above is used to form a dispersion film on a substrate. Note that the dispersion liquid is produced by the same method as previously described.

The method by which the dispersion film is formed can be selected as appropriate depending on the objective, without any specific limitations, and is preferably a wet film formation method in terms of physical properties, convenience, production costs, and so forth.

The wet film formation method can be selected as appropriate depending on the objective, without any specific limitations, and may for example be a commonly known method such as a coating method, a spraying method, or a printing method.

The coating method can be selected as appropriate depending on the objective, without any specific limitations, and may for example be micro gravure coating, wire bar coating, direct gravure coating, die coating, dipping, spray coating, reverse roll coating, curtain coating, comma coating, knife coating, or spin coating.

The spraying method can be selected as appropriate depending on the objective, without any specific limitations.

The printing method can be selected as appropriate depending on the objective, without any specific limitations, and may for example be relief printing, offset printing, gravure printing, intaglio printing, rubber plate printing, screen printing, or inkjet printing.

The curing step is a step in which the dispersion film formed on the substrate is cured to obtain a cured product (in FIGS. 1-5, the cured product is the binder layer 8 that includes the metal nanowires 6 having the colored compound 7 adsorbed onto the surfaces thereof).

In the curing step, solvent in the dispersion film formed on the substrate is first removed by drying. Removal of the solvent by drying may be carried out by natural drying or heated drying. After the drying, curing treatment of the uncured binder is carried out such that the metal nanowires are in a dispersed state in the cured binder. The curing treatment can be carried out by heating and/or irradiation with activating energy rays.

The calendering step is a step that is carried out in order to improve surface smoothness and impart glossiness on the surface.

The calendering can also reduce the sheet resistance value of the transparent conductive film that is produced.

The overcoating layer formation step is a step in which an overcoating layer is formed on the cured product that has been formed from the dispersion film.

The overcoating layer can for example be formed by applying, onto the cured product, a coating liquid for overcoating layer formation containing a specific material and curing the applied coating liquid.

The pattern electrode formation step is a step in which a pattern electrode is formed by a commonly known photolithographic process after the transparent conductive film has been formed on the substrate. Through this step, the transparent conductive film according to the present disclosure can be adopted in a sensor electrode for a capacitive touch panel. Furthermore, in a situation in which the curing treatment in the curing step includes irradiation with activating energy rays, the curing treatment may be used for mask exposure/development in formation of the pattern electrode. Furthermore, patterning may be performed by laser etching.

<Input Device>

An input device according to the present disclosure includes the transparent conductive film according to the present disclosure described above. Through use of the transparent conductive film according to the present disclosure, it is possible to achieve display in which black floating does not occur and in which yellow coloring is suppressed to provide excellent external appearance.

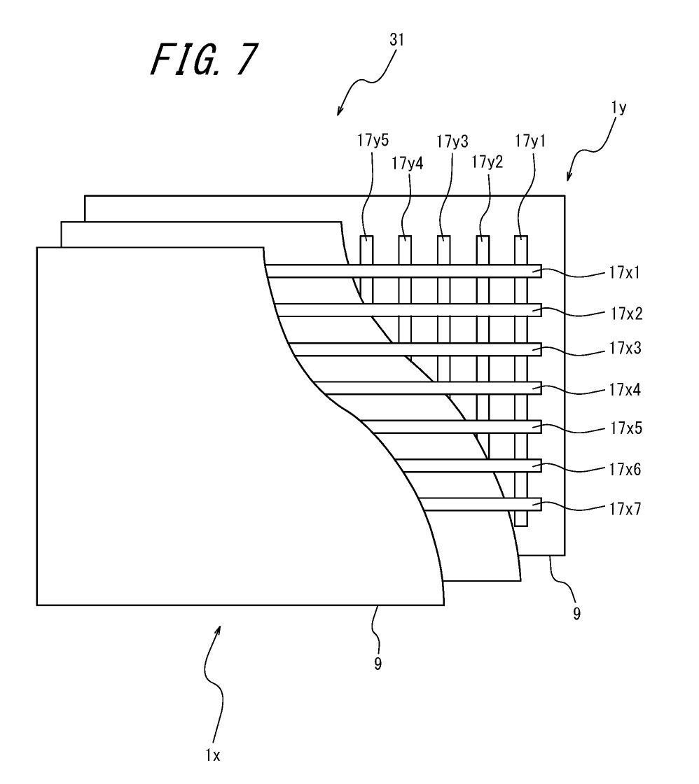

FIG. 7 illustrates an example of the main elements of configuration of the input device in which the transparent conductive film according to the present disclosure is used. An input device 31 illustrated in FIG. 7 is for example a capacitive touch panel that is disposed on a display surface of a display panel. The input device 31 is formed using two transparent conductive films 1x and 1y. The transparent conductive films 1x and 1y include electrode patterns 17x1, 17x2, . . . and 17y1, 17y2, . . . that are arranged in parallel on respective transparent substrates 9. The transparent conductive films 1x and 1y are arranged in opposition to one another with the electrode patterns 17x1, 17x2, . . . and the electrode patterns 17y1, 17y2, . . . intersecting perpendicularly in x-y directions, and are bonded together via an adhesive insulating film.

Furthermore, although not shown in FIG. 7, the input device 31 includes a plurality of terminals that are wired such as to apply a measurement voltage individually to each of the electrode patterns 17x1, 17x2, . . . and 17y1, 17y2, . . . of the transparent conductive films 1x and 1y.

The information input device 31 applies a measurement voltage alternately to the electrode patterns 17x1, 17x2, . . . of the transparent conductive film 1x and the electrode patterns 17y1, 17y2, . . . of the transparent conductive film 1y. When the surface of the transparent substrate 11 is touched by a finger or a stylus pen in this state, capacitance at each section within the information input device 31 changes and, as a result, the measurement voltage of each of the electrode patterns 17x1, 17x2, . . . and 17y1, 17y2, . . . changes. This change is dependent on the distance from the position touched by the finger or stylus pen and is greatest at the position touched by the finger or stylus pen. Therefore, a position at which the change in measurement voltage is greatest, which is addressed by electrode patterns 17xn and 17yn, is detected as the position touched by the finger or stylus pen.

It should be noted that the input device according to the present disclosure is not limited to the input device 31 having the configuration described above and can be applied to a wide range of information input devices that include transparent conductive films. For example, the input device according to the present disclosure may be a resistive film touch panel. Even in such a configuration, the same effects as in the input device 31 illustrated in FIG. 7 can be obtained.

<Organic Electroluminescent Lighting Device>

An organic electroluminescent lighting device according to the present disclosure includes the input device according to the present disclosure described above. Through inclusion of the input device according to the present disclosure, it is possible to achieve display in which yellow coloring is suppressed to provide excellent external appearance.

### EXAMPLES

The following provides a more specific description of the present disclosure based on examples. However, the present disclosure is not in any way limited to the following examples.

### Example 1-1

A dispersion liquid of silver nanowires [1] (AgNW-25 (average diameter 25 nm, average length 23 μm) produced by Seashell Technology, LLC.) was used as metal nanowires.

A colored compound solution was prepared by the following procedure.

A phthalocyanine derivative in an amount of 10 mg was added into 10 g of 1:1 water/ethylene glycol used as a solvent and was dissolved using an ultrasonic cleaner for 60 minutes. Thereafter, the solution was filtered using a PTFE filter having a pore diameter of 3 μm and the filtrate was used as the colored compound solution.

Next, 2 g of the silver nanowire [1] dispersion liquid was added to the colored compound solution and stirring was performed for 12 hours at room temperature to cause adsorption of a phthalocyanine-based complex compound onto the silver nanowires. As a result, a mixed solution was obtained that contained the silver nanowires having the colored compound adsorbed thereon and unattached colored compound. Thereafter, the mixed solution was added into a fluorine resin filter paper tube No. 89 produced by Advantec MFS, Inc. and washing was performed repeatedly using 3:1 water/ethanol as a solvent until the filtrate appeared colorless and transparent to the naked eye.

A coating dispersion liquid was prepared by mixing a dispersion liquid containing silver nanowires [A] having a colored compound adsorbed thereon, which were obtained through the previous step, with other materials in the amounts shown below.

Silver nanowires [A]: 0.06 mass % (net weight of silver nanowires)

Hydroxypropyl methylcellulose (produced by Sigma-Aldrich Co. LLC.): 0.09 mass %

Water: 89.85 mass %

Ethanol: 10 mass %

The prepared coating dispersion liquid was coated onto a transparent substrate by a 10 count coil bar to form a transparent conductive film for use as a sample. The mass per unit area of the silver nanowires in the prepared transparent conductive film was 0.012 g/m². The transparent substrate was PET (Lumirror U34 produced by Toray Industries, Inc.) having a film thickness of 100 μm.

Next, warm air was blown onto the coated surface using a dryer with the coated surface exposed to the atmosphere in order to remove solvent from the coated film by drying, and drying was then performed for a further 2 minutes at 120° C.

The aforementioned phthalocyanine derivative was prepared by the following procedure.

Alcian blue 8GX (produced by Sigma-Aldrich Co. LLC.) and sodium 2-mercapto-1-ethanesulfonate (produced by Wako Pure Chemical Industries, Ltd.) were mixed with a weight ratio of 1:2 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

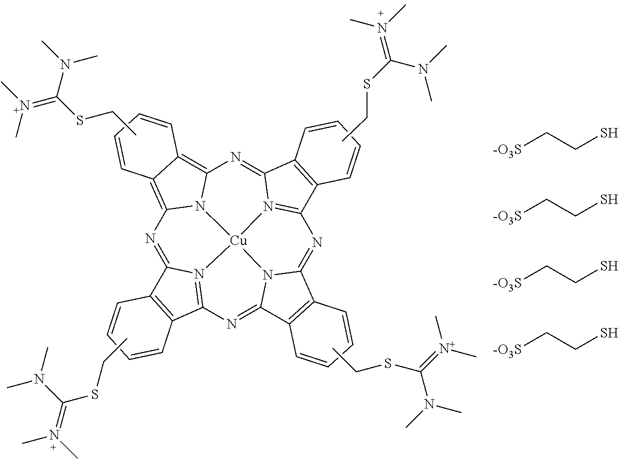

### Example 1-2

A transparent conductive film for use as a sample was prepared in the same way as in Example 1-1 with the exception that the coating dispersion liquid in Example 1-1 was prepared using the amounts of materials shown below.

Silver nanowires [A]: 0.11 mass % (net weight of silver nanowires)

Hydroxypropyl methylcellulose (produced by Sigma-Aldrich Co. LLC.): 0.16 mass %

Water: 89.73 mass %

Ethanol: 10 mass %

The mass per unit area of the silver nanowires in the prepared transparent conductive film was 0.024 g/m².

### Example 2-1

A transparent conductive film for use as a sample was prepared using the same conditions as in Example 1-1 with the exception that surface treatment was performed using a phthalocyanine derivative described below, and a dispersion liquid containing silver nanowires [B] having a colored compound adsorbed thereon, which were obtained through this surface treatment, was used as the coating dispersion liquid.

The phthalocyanine derivative was prepared by the following procedure.

Alcian blue 8GX (produced by Sigma-Aldrich Co. LLC.) and sodium butanesulfonate (produced by Tokyo Chemical Industry Co., Ltd.) were mixed with a weight ratio of 1:2 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

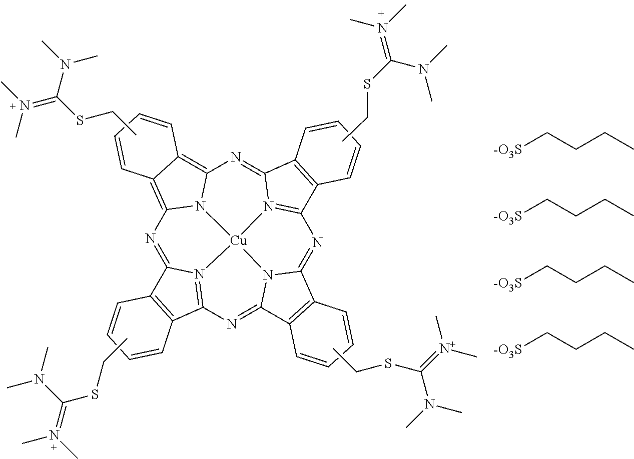

### Example 2-2

A transparent conductive film for use as a sample was prepared using the same conditions as in Example 1-2 with the exception that the silver nanowires [B] described in Example 2-1 were used.

### Example 3-1

A transparent conductive film for use as a sample was prepared using the same conditions as in Example 1-1 with the exception that surface treatment was performed using a phthalocyanine derivative described below, and a dispersion liquid containing silver nanowires [C] having a colored compound adsorbed thereon, which were obtained through this surface treatment, was used as the coating dispersion liquid.

The phthalocyanine derivative was prepared by the following procedure.

Alcian blue-tetrakis(methylpyridinium) chloride (produced by Sigma-Aldrich Co. LLC.) and disodium 1,2-ethanedisulfonate (produced by Tokyo Chemical Industry Co., Ltd.) were mixed with a weight ratio of 1:2 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

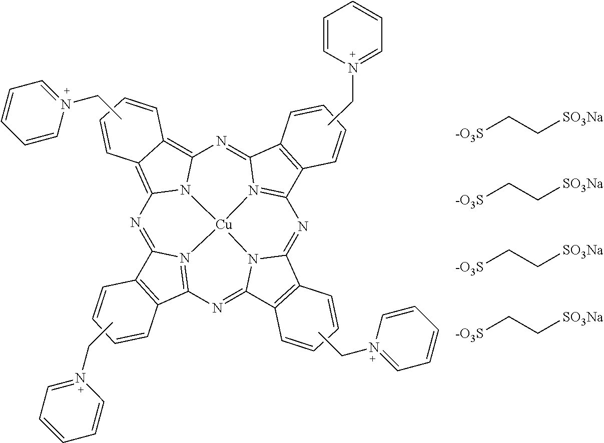

### Example 3-2

A transparent conductive film for use as a sample was prepared using the same conditions as in Example 1-2 with the exception that the silver nanowires [C] described in Example 3-1 were used.

### Example 4-1

A transparent conductive film for use as a sample was prepared using the same conditions as in Example 1-1 with the exception that surface treatment was performed using a phthalocyanine derivative described below, and a dispersion liquid containing silver nanowires [D] having a colored compound adsorbed thereon, which were obtained through this surface treatment, was used as the coating dispersion liquid.

The phthalocyanine derivative was prepared by the following procedure.

Alcian blue-tetrakis(methylpyridinium) chloride (produced by Sigma-Aldrich Co. LLC.) and sodium isethionate (produced by Tokyo Chemical Industry Co., Ltd.) were mixed with a weight ratio of 1:2 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

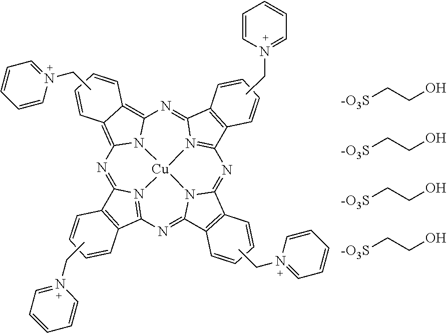

### Example 4-2

A transparent conductive film for use as a sample was prepared using the same conditions as in Example 1-2 with the exception that the silver nanowires [D] described in Example 4-1 were used.

### Example 5-1

A transparent conductive film for use as a sample was prepared using the same conditions as in Example 1-1 with the exception that surface treatment was performed using a phthalocyanine derivative described below, and a dispersion liquid containing silver nanowires [E] having a colored compound adsorbed thereon, which were obtained through this surface treatment, was used as the coating dispersion liquid.

The phthalocyanine derivative was prepared by the following procedure.

Alcian blue-tetrakis(methylpyridinium) chloride (produced by Sigma-Aldrich Co. LLC.) and potassium 3-(methacryloyloxy)propanesulfonate (produced by Tokyo Chemical Industry Co., Ltd.) were mixed with a weight ratio of 1:2 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

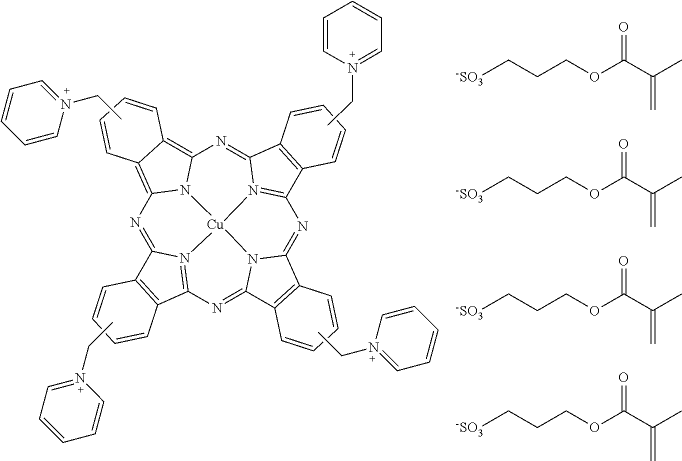

### Example 5-2

A transparent conductive film for use as a sample was prepared using the same conditions as in Example 1-2 with the exception that the silver nanowires [E] described in Example 5-1 were used.

### Example 6-1

A transparent conductive film for use as a sample was prepared using the same conditions as in Example 1-1 with the exception that surface treatment was performed using a phthalocyanine derivative described below, and a dispersion liquid containing silver nanowires [F] having a colored compound adsorbed thereon, which were obtained through this surface treatment, was used as the coating dispersion liquid.

The phthalocyanine derivative was prepared by the following procedure.

Phthalocyanine tetrasulfonate hydrate (produced by Sigma-Aldrich Co. LLC.) and 2-aminoethanethiol (produced by Tokyo Chemical Industry Co., Ltd.) were mixed with a weight ratio of 1:2 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

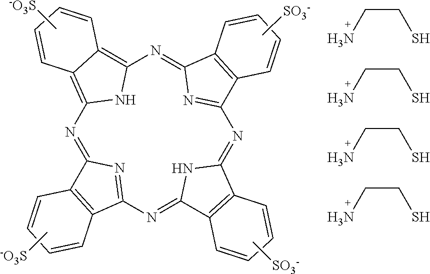

### Example 6-2

A transparent conductive film for use as a sample was prepared using the same conditions as in Example 1-2 with the exception that the silver nanowires [F] described in Example 6-1 were used.

### Example 7-1

A transparent conductive film for use as a sample was prepared using the same conditions as in Example 1-1 with the exception that surface treatment was performed using a phthalocyanine derivative described below, and a dispersion liquid containing silver nanowires [G] having a colored compound adsorbed thereon, which were obtained through this surface treatment, was used as the coating dispersion liquid.

The phthalocyanine derivative was prepared by the following procedure.

Trimellitic anhydride, urea, ammonium molybdate, and zinc chloride were added to nitrobenzene, were stirred and heated under reflux, and a precipitate was collected. Next, sodium hydroxide was added to the precipitate to cause hydrolysis thereof and then hydrochloric acid was added in order to provide acidic conditions and thereby yield zinc phthalocyanine tetracarboxylic acid.

Next, the zinc phthalocyanine tetracarboxylic acid and 2-aminoethanethiol (produced by Tokyo Chemical Industry Co., Ltd.) were mixed with a weight ratio of 1:2 in methanol to prepare a mixed solution. The mixed solution was caused to react for 60 minutes using an ultrasonic cleaner and the resultant reaction liquid was filtered using a 3 μm PTFE filter. Filtered-off solid was washed three times with methanol and was then dried under reduced pressure to yield a phthalocyanine derivative represented by the following formula.

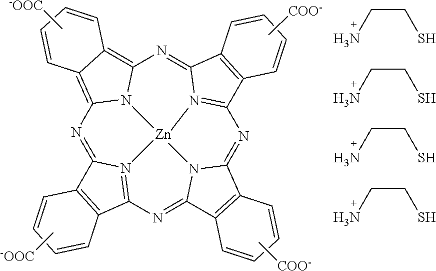

### Example 7-2

A transparent conductive film for use as a sample was prepared using the same conditions as in Example 1-2 with the exception that the silver nanowires [G] described in Example 7-1 were used.

### Example 8-1

A transparent conductive film for use as a sample was prepared using the same conditions as in Example 1-1 with the exception that surface treatment was performed using a phthalocyanine derivative described below, and a dispersion liquid containing silver nanowires [H] having a colored compound adsorbed thereon, which were obtained through this surface treatment, was used as the coating dispersion liquid.

The phthalocyanine derivative was prepared by the following procedure.

Alcian blue 8GX (produced by Sigma-Aldrich Co. LLC.) and sodium 1-octadecanesulfonate (produced by Tokyo Chemical Industry Co., Ltd) were mixed with a weight ratio of 1:4 in an aqueous medium. The mixed solution was caused to react for 60 minutes using an ultrasonic cleaner and the resultant reaction liquid was filtered using a 3 μm PTFE filter. Filtered-off solid was washed three times with water and was then dried under reduced pressure to yield a phthalocyanine derivative represented by the following formula.

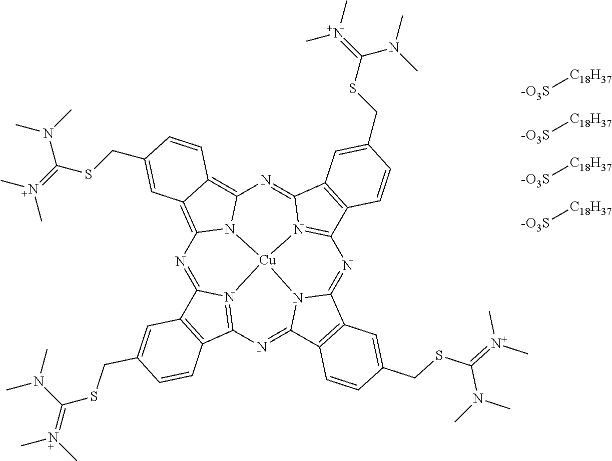

### Example 8-2

A transparent conductive film for use as a sample was prepared using the same conditions as in Example 1-2 with the exception that the silver nanowires [H] described in Example 8-1 were used.

### Example 9-1

A transparent conductive film for use as a sample was prepared using the same conditions as in Example 1-1 with the exception that a dispersion liquid of silver nanowires [2] (AW-030 (average diameter 30 nm, average length 20 μm) produced by Zhejiang Kechuang Advanced Materials Co.) was used as the metal nanowires and a dispersion liquid containing silver nanowires [I] having a colored compound adsorbed thereon was used as the coating dispersion liquid. The coating dispersion liquid was prepared using the amounts of materials shown below.

Silver nanowires [I]: 0.06 mass % (net weight of silver nanowires)

Hydroxypropyl methylcellulose (produced by Sigma-Aldrich Co. LLC.): 0.09 mass %

Water: 89.85 mass %

Ethanol: 10 mass %

The mass per unit area of the silver nanowires in the prepared transparent conductive film was 0.012 g/m².

### Example 9-2

A transparent conductive film for use as a sample was prepared using the same conditions as in Example 9-1 with the exception that the coating dispersion liquid was prepared with the amounts of materials shown below.

Silver nanowires [I]: 0.11 mass % (net weight of silver nanowires)

Hydroxypropyl methylcellulose (produced by Sigma-Aldrich Co. LLC.): 0.16 mass %

Water: 89.73 mass %

Ethanol: 10 mass %

The mass per unit area of the silver nanowires in the prepared transparent conductive film was 0.024 g/m².

### Example 10-1

A transparent conductive film for use as a sample was prepared using the same conditions as in Example 1-1 with the exception that surface treatment was performed using the following chromium complex derivative and a dispersion liquid containing silver nanowires [J] having a colored compound adsorbed thereon, which were obtained through this surface treatment, was used as the coating dispersion liquid. Note that calendering (nip width 1 mm, load 4 kN, speed 1 m/minute) was carried out after coating and drying of the coating dispersion liquid.

The chromium complex derivative was prepared by the following procedure.

Lanyl Black BG E/C produced by Taoka Chemical Co., Ltd. and 2-aminoethanethiol hydrochloride produced by Wako Pure Chemical Industries, Ltd. were mixed with a weight ratio of 4:1 in an aqueous medium. The mixed solution was caused to react for 100 minutes using an ultrasonic cleaner and was then left for 15 hours. The reaction liquid was filtered using a mixed cellulose ester type membrane filter having a pore diameter of 3 Filtered-off solid was washed three times with water and was then dried at 100° C. in a vacuum oven to yield the chromium complex derivative.

### Example 10-2

A transparent conductive film for use as a sample was prepared using the same conditions as in Example 1-2 with the exception that the silver nanowires [J] described in Example 10-1 were used. Note that calendering (nip width 1 mm, load 4 kN, speed 1 m/minute) was carried out after coating and drying of the coating dispersion liquid.

### Example 11-1

A transparent conductive film was prepared using the same conditions as in Example 1-1 with the exception that 1 mg of the phthalocyanine derivative described in Example 1-1 was added into 10 g of 1:1 water/ethanol as a solvent and was dissolved using an ultrasonic cleaner for 60 minutes, thereafter the solution was filtered using a PTFE filter having a pore diameter of 3 μm and the resultant solution was used as a colored compound solution, and a dispersion liquid containing silver nanowires [K] having a colored compound adsorbed thereon, which were obtained using the colored compound solution, was used as the coating dispersion liquid.

### Example 11-2

A transparent conductive film for use as a sample was prepared using the same conditions as in Example 1-2 with the exception that the silver nanowires [K] described in Example 11-1 were used.

### Comparative Example 1-1

A transparent conductive film for use as a sample was prepared using the same conditions as in Example 1-1 with the exception that the coating dispersion liquid was prepared with the amounts of materials shown below.

Silver nanowires [1]: 0.06 mass % (net weight of silver nanowires)

Hydroxypropyl methylcellulose (produced by Sigma-Aldrich Co. LLC.): 0.09 mass %

Water: 89.85 mass %

Ethanol: 10 mass %

The mass per unit area of the silver nanowires in the prepared transparent conductive film was 0.012 g/m².

### Comparative Example 1-2

A transparent conductive film for use as a sample was prepared using the same conditions as in Example 1-1 with the exception that the coating dispersion liquid was prepared with the amounts of materials shown below.

Silver nanowires [1]: 0.11 mass % (net weight of silver nanowires)

Hydroxypropyl methylcellulose (produced by Sigma-Aldrich Co. LLC.): 0.16 mass %

Water: 89.73 mass %

Ethanol: 10 mass %

The mass per unit area of the silver nanowires in the prepared transparent conductive film was 0.024 g/m².

### Comparative Example 2-1

A transparent conductive film for use as a sample was prepared using the same conditions as in Comparative Example 1-1 with the exception that the silver nanowires [2] described in Example 9-1 were used as metal nanowires.

### Comparative Example 2-2

A transparent conductive film for use as a sample was prepared using the same conditions as in Comparative Example 1-2 with the exception that the silver nanowires [2] described in Example 9-1 were used as metal nanowires.

<Physical Property Values of Transparent Conductive Films>

The sample transparent conductive films prepared in the examples and comparative examples was used to measure or calculate (A) a sheet resistance value, (B) a transmission b* value, (C) [transmission b* value for sheet resistance value of 40 Ω/sq.]−[transmission b* value for sheet resistance value of 100 Ω/sq.], and (D) an adsorbed amount of colored compound with respect to silver nanowires. The measurement results are shown in Table 1.

An EC-80P (product name; produced by Napson Corporation) was used to measure (A) the sheet resistance value. Note that a sheet resistance value of no greater than 200 Ω/sq. is preferable.

A transmission spectrum of each transparent conductive film was measured using a Color i5 produced by X-Rite Inc. and a transmission b* value was calculated from the transmission spectrum. A transmission b* value of the substrate by itself was subtracted from the calculated value to obtain a transmission b* value for just the transparent conductive film, which was taken to be (B) the transmission b* value. A D65 light source was used as a light source for measuring the transmission spectrum.

The value of (C) [transmission b* value for sheet resistance value of 40 Ω/sq.]−[transmission b* value for sheet resistance value of 100 Ω/sq.] was calculated from the transmission b* values of samples for which the metal nanowires having the colored compound adsorbed thereon were the same (for example, the sample in Example 1-1 and the sample in Example 1-2).

With regards to (D) the adsorbed amount of colored compound with respect to silver nanowires, the silver nanowire dispersion liquid used to prepare the sample in each of the examples and comparative examples was dripped onto a micro-grid for TEM, the silver nanowire dispersion liquid was dried overnight, and then the thickness of an organic layer on the surfaces of the silver nanowires was measured using an EM-002B produced by Topcon Technohouse Corporation. Observation was performed at an accelerating voltage of 200 kV. An average value was calculated for measurements performed at 20 arbitrary locations and the calculated average value was taken to be the adsorbed amount.

<Evaluation>

The sample transparent conductive films obtained in the examples and comparative examples were evaluated as follows. The evaluation results are shown in Table 1.

(E) Total Light Transmittivity

An HM-150 (produced by Murakami Color Research Laboratory Co., Ltd.) was used to measure the total light transmittivity of each of the sample transparent conductive films in accordance with JIS K7136. Note that a higher total light transmittivity indicates a better result.
(F) Haze Value

An HM-150 (produced by Murakami Color Research Laboratory Co., Ltd.) was used to measure a haze value of each of the sample transparent conductive films in accordance with JIS K7136. Note that a smaller haze value indicates a better result.

(G) ΔReflection L* Value

A Δreflection L* value of each sample transparent conductive film was evaluated by attaching black plastic tape (VT-50 produced by Nichiban Co, Ltd.) at the silver nanowire layer-side and performing evaluation from the opposite side to the silver nanowire layer-side in accordance with JIS Z8722 using a Color i5 produced by X-Rite Inc. The light source was a D65 light source and an average value of measurements performed at three arbitrary locations by an SCE (specular component excluded) method was taken to be a reflection L value.

Herein, the Δreflection L* value can be calculated using the following formula.

ΔReflection L* value=(Reflection L* value of transparent electrode including substrate)−(Reflection L* value of substrate)

Note that a smaller Δreflection L* value indicates a better result.

(H) External Appearance (Presence of Yellow Coloring)

The external appearance of each sample transparent conductive film was evaluated by visually observing the sample transparent conductive film and evaluating the presence of yellow coloring in accordance with the following standard. Note that “1” is the best result and “3” is the poorest result.

1: Yellow coloring in external appearance is not observed for either of the sample transparent conductive film having a resistance value of 100 Ω/sq. and the sample transparent conductive film having a resistance value of 40 Ω/sq.

2: Slight yellow coloring is observed only for the sample transparent conductive film having a resistance value of 40 Ω/sq.

3: Yellow coloring is observed for the sample transparent conductive film having a resistance value of 40 Ω/sq.

TABLE 1

| | Conditions | | Physical property values of transparent conductive film | | | |
|---|---|---|---|---|---|---|
| | | Metal | (A) | (B) | | (D) |
| | | nanowires having | Sheet | Transmission | (C) | Adsorbed amount |
| | | adsorbed colored | resistance | b* | b* (40 Ω/sq.) − | of colored |
| | Metal nanowires | compound | value | value | b* (100 Ω/sq.) | compound (nm) |
| Example 1-1 | Silver nanowires [1] | Silver nanowires [A] | 100 | 0.18 | 0.39 | 1.1 |
| Example 1-2 | Silver nanowires [1] | Silver nanowires [A] | 40 | 0.57 | | 1.1 |
| Example 2-1 | Silver nanowires [1] | Silver nanowires [B] | 100 | 0.18 | 0.39 | 1.2 |
| Example 2-2 | Silver nanowires [1] | Silver nanowires [B] | 40 | 0.57 | | 1.2 |
| Example 3-1 | Silver nanowires [1] | Silver nanowires [C] | 100 | 0.18 | 0.39 | 1.0 |
| Example 3-2 | Silver nanowires [1] | Silver nanowires [C] | 40 | 0.57 | | 1.0 |
| Example 4-1 | Silver nanowires [1] | Silver nanowires [D] | 100 | 0.18 | 0.39 | 1.1 |
| Example 4-2 | Silver nanowires [1] | Silver nanowires [D] | 40 | 0.57 | | 1.1 |
| Example 5-1 | Silver nanowires [1] | Silver nanowires [E] | 100 | 0.18 | 0.39 | 1.3 |
| Example 5-2 | Silver nanowires [1] | Silver nanowires [E] | 40 | 0.57 | | 1.3 |
| Example 6-1 | Silver nanowires [1] | Silver nanowires [F] | 100 | 0.18 | 0.39 | 1.0 |
| Example 6-2 | Silver nanowires [1] | Silver nanowires [F] | 40 | 0.57 | | 1.0 |
| Example 7-1 | Silver nanowires [1] | Silver nanowires [G] | 100 | 0.18 | 0.39 | 1.2 |
| Example 7-2 | Silver nanowires [1] | Silver nanowires [G] | 40 | 0.57 | | 1.2 |
| Example 8-1 | Silver nanowires [1] | Silver nanowires [H] | 100 | 0.18 | 0.39 | 1.1 |
| Example 8-2 | Silver nanowires [1] | Silver nanowires [H] | 40 | 0.57 | | 1.1 |
| Example 9-1 | Silver nanowires [2] | Silver nanowires [I] | 100 | −0.01 | 0.38 | 1.2 |
| Example 9-2 | Silver nanowires [2] | Silver nanowires [I] | 40 | 0.37 | | 1.2 |
| Example 10-1 | Silver nanowires [1] | Silver nanowires [J] | 100 | 0.21 | 0.49 | 1.3 |
| Example 10-2 | Silver nanowires [1] | Silver nanowires [J] | 40 | 0.70 | | 1.3 |
| Example 11-1 | Silver nanowires [1] | Silver nanowires [K] | 100 | 0.20 | 0.47 | 0.7 |
| Example 11-2 | Silver nanowires [1] | Silver nanowires [K] | 40 | 0.67 | | 0.7 |
| Comparative | Silver nanowires [1] | — | 100 | 0.23 | 0.58 | — |
| Example 1-1 | | | | | | |
| Comparative | Silver nanowires [1] | — | 40 | 0.81 | | — |
| Example 1-2 | | | | | | |
| Comparative | Silver nanowires [2] | — | 100 | 0.04 | 0.7 | — |
| Example 2-1 | | | | | | |
| Comparative | Silver nanowires [2] | — | 40 | 0.74 | | — |
| Example 2-2 | | | | | | |

| | Evaluation | | | |
|---|---|---|---|---|
| | (E) | | (G) | (H) |
| | Total light | (F) | ΔReflection L* | External |
| | transmittivity | Haze value | value | appearance |
| Example 1-1 | 91.5 | 0.9 | 1.7 | 1 |
| Example 1-2 | 91.1 | 1.4 | 3.7 | |
| Example 2-1 | 91.6 | 0.9 | 1.7 | 1 |
| Example 2-2 | 91.2 | 1.4 | 3.7 | |
| Example 3-1 | 91.5 | 0.9 | 1.7 | 1 |
| Example 3-2 | 91.1 | 1.4 | 3.7 | |
| Example 4-1 | 91.4 | 0.9 | 1.7 | 1 |
| Example 4-2 | 91.0 | 1.4 | 3.7 | |
| Example 5-1 | 91.5 | 0.9 | 1.7 | 1 |
| Example 5-2 | 91.1 | 1.4 | 3.7 | |
| Example 6-1 | 91.6 | 0.9 | 1.7 | 1 |
| Example 6-2 | 91.2 | 1.4 | 3.7 | |
| Example 7-1 | 91.5 | 0.9 | 1.7 | 1 |
| Example 7-2 | 91.1 | 1.4 | 3.7 | |
| Example 8-1 | 91.5 | 0.9 | 1.7 | 1 |
| Example 8-2 | 91.1 | 1.4 | 3.7 | |
| Example 9-1 | 91.3 | 1.0 | 2.0 | 1 |
| Example 9-2 | 90.9 | 1.5 | 4.5 | |
| Example 10-1 | 91.4 | 1.0 | 2.0 | 2 |
| Example 10-2 | 91.0 | 1.5 | 4.0 | |
| Example 11-1 | 91.6 | 1.0 | 1.9 | 2 |
| Example 11-2 | 91.2 | 1.5 | 4.0 | |
| Comparative | 91.6 | 1.1 | 2.5 | 3 |
| Example 1-1 | | | | |
| Comparative | 91.3 | 1.6 | 4.5 | |
| Example 1-2 | | | | |
| Comparative | 91.4 | 1.2 | 2.9 | 3 |
| Example 2-1 | | | | |
| Comparative | 91.1 | 1.7 | 5.3 | |
| Example 2-2 | | | | |

Table 1 shows that the samples in the examples demonstrated superior results to the samples in the comparative examples in terms of haze value, Δreflection L value, and external appearance.

Furthermore, the difference represented by [transmission b* value for sheet resistance value of 40 Ω/sq.]−[transmission b* value for sheet resistance value of 100 Ω/sq.] was small for the samples in the examples, indicating that the same external appearance can be obtained over a wide range of resistance values.

### INDUSTRIAL APPLICABILITY

According to the present disclosure, it is possible to provide a dispersion liquid that enables formation of a transparent conductive film in which diffuse reflection of light by the surfaces of metal nanowires is prevented while maintaining good transparency, and in which yellow coloring is suppressed to provide the transparent conductive film with excellent external appearance.

Furthermore, it is possible to provide, using the dispersion liquid, a transparent conductive film in which good transparency is maintained and yellow coloring is suppressed to provide the transparent conductive film with excellent external appearance, and it is possible to provide, through use of the transparent conductive film as an electrode, an input device and an organic electroluminescent lighting device having excellent external appearance and in which black floating does not occur.

1. A dispersion liquid comprising:
metal nanowires and
a colored compound adsorbed onto the metal nanowires, wherein
a transmission b* value of a transparent conductive film formed from the dispersion liquid is no greater than 0.7.

2. The dispersion liquid of claim 1, wherein
a difference between the transmission b* value in a situation in which the transparent conductive film has a sheet resistance value of 40 Ω/sq. and the transmission b* value in a situation in which the transparent conductive film has a sheet resistance value of 100 Ω/sq. is no greater than 0.4.

3. The dispersion liquid of claim 1, wherein
the colored compound is a phthalocyanine-based complex compound.

4. The dispersion liquid of claim 3, wherein
the phthalocyanine-based complex compound is represented by general formula (1) shown below, 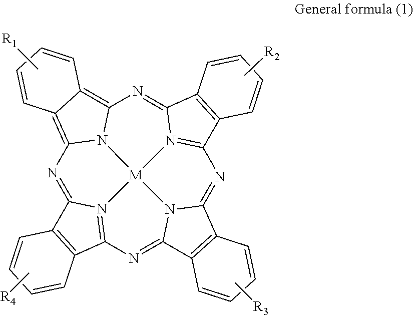
M in general formula (1) is any of Cu, Fe, Ti, V, Ni, Pd, Pt, Pb, Si, Bi, Cd, La, Tb, Ce, Be, Mg, Co, Ru, Mn, Cr, Mo, Sn, and Zn, and may be present or absent,
one or more of R₁ to R₄ in general formula (1) are present on a phthalocyanine moiety, each include an ion represented by any general formula in general formula group (A) shown below, and may be the same or different to one another, 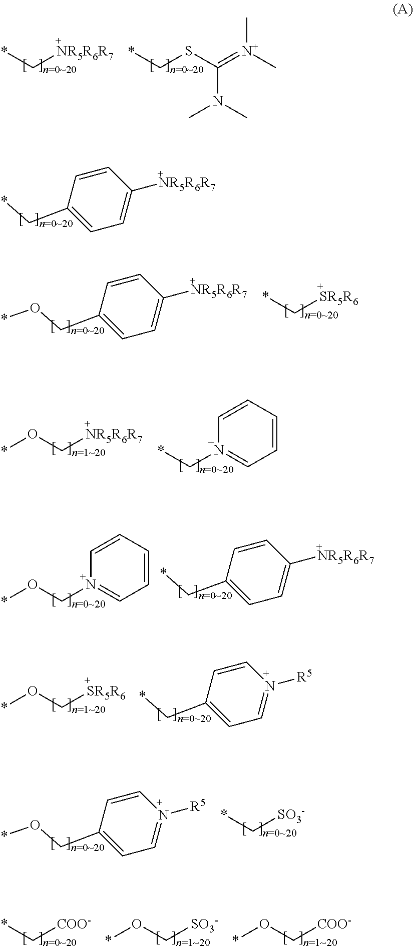
R₅ to R₇ in general formula group (A) are each hydrogen or a hydrocarbon group, and may be the same or different to one another,
R₁ to R₄ in general formula (1) each further include a counter ion represented by any general formula in general formula group (B) shown below, 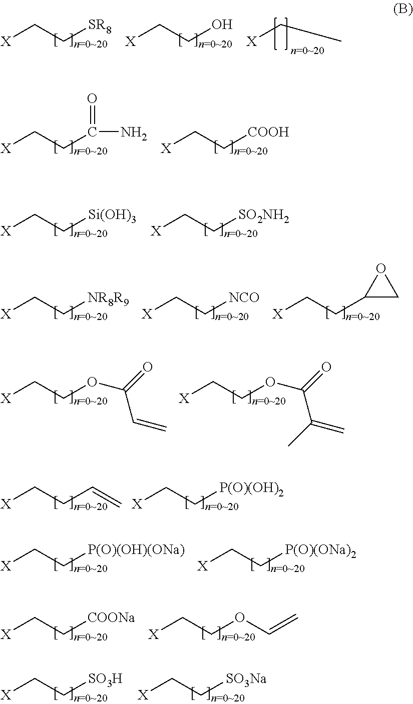
X in general formula group (B) is an ion represented by SO₃⁻, COO⁻, PO₃H⁻, PO₃²⁻, N⁺R₈R₉R₁₀, or PhN⁺R₈R₉R₁₀, an ion represented by general formula (2) shown below, or an ion represented by structural formula (1) shown below, 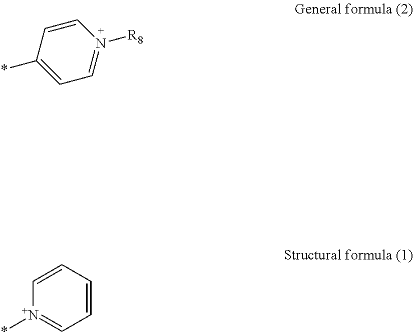
and R₈ to R₁₀ in general formula group (B), N⁺R₈R₉R₁₀, PhN⁺R₈R₉R₁₀, and general formula (2) are each hydrogen or a hydrocarbon group, and may be the same or different to one another.

5. The dispersion liquid of claim 1, wherein
a Δreflection L* value of the transparent conductive film is no greater than 10.

6. A transparent conductive film comprising:
metal nanowires and
a colored compound adsorbed onto the metal nanowires, wherein
a transmission b* value of the transparent conductive film is no greater than 0.7.

7. An input device comprising the transparent conductive film of claim 6.

8. An organic electroluminescent lighting device comprising the input device of claim 7.
